(19) United States
(12) Patent Application Publication
(10) Pub. No.: US 2025/0351486 A1
(43) Pub. Date: Nov. 13, 2025

(54) SEMICONDUCTOR DEVICE AND METHOD

(71) Applicant: Taiwan Semiconductor Manufacturing Co., Ltd., Hsinchu (TW)

(72) Inventors: Wei-Ting Chang, Hsinchu (TW); Meng-Han Chou, Hsinchu (TW); Su-Hao Liu, Jhongpu Township (TW); Chien-Hao Chen, Chuangwei Township (TW); Szu-Ying Chen, Hsinchu (TW)

(21) Appl. No.: 18/813,871

(22) Filed: Aug. 23, 2024

Related U.S. Application Data
(60) Provisional application No. 63/645,512, filed on May 10, 2024.

(51) Int. Cl. H01L 29/06; H01L 21/04; H01L 21/8238; H01L 27/092; H01L 29/08; H01L 29/66

(52) U.S. Cl. CPC H10D 62/121; H01L 21/0465; H10D 30/014; H10D 62/151; H10D 64/017; H10D 64/018; H10D 84/0167; H10D 84/017; H10D 84/038; H10D 84/85

(57) ABSTRACT

In an embodiment, a method may include forming a multi-layer stack over a substrate. The multi-layer stack has alternating layers of first semiconductor layers and second semiconductor layers. The method may also include removing the first semiconductor layers. Furthermore, the method may include forming a disposable material between the second semiconductor layers. In addition, the method may include performing a first implantation process on the disposable material and the second semiconductor layers. Moreover, the method may include forming source/drain regions adjacent to the second semiconductor layers and the disposable material. The method may also include replacing the disposable material with a metal gate structure.

### PRIORITY CLAIM AND CROSS-REFERENCE

This application claims the benefit of U.S. Provisional Application No. 63/645,512 filed on May 10, 2024, entitled “Sheet Formation Approach Via Implant Under DOI Scheme,” which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A, 5B, 6A, 6B, 7A, 7B, 7C, 8A, 8B, 9A, 9B, 9C, 10A, 10B, 10C, 10D, 10E, 11A, 11B, 11C, 11D, 12A, 12B, 12C, 12D, 12E, 12F, 13A, 13B, 14A, 14B, 15A, 15B, 16A, 16B, 16C, 17A, 17B, 17C, 18A, 18B, 18C, 19A, 19B, and 19C illustrate varying views of intermediary steps of manufacturing a nano-FET transistor, in accordance with some embodiments.

FIG. 20 illustrates a cross-sectional view of an intermediary step of manufacturing a nano-FET transistor, in accordance with some embodiments.

FIGS. 21, 22A, 22B, and 22C illustrate cross-sectional views of an intermediary step of manufacturing a nano-FET transistor, in accordance with some embodiments.

FIG. 23 illustrates a cross-sectional view of an intermediary step of manufacturing a nano-FET transistor, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to a method for nano-FET formation using a disposable oxide interposer (DOI) scheme. This method may involve a tilt implant or plasma doping approach to increase the DOI oxide etching rate. By enhancing the etching rate, the method may reduce the likelihood of residual oxide remaining after the DOI removal step, a challenge often encountered in conventional sheet formation processes.

In some embodiments, the method may also mitigate the risk of over-etching the sheet during the DOI oxide etching process. Over-etching can potentially lead to source/drain epitaxial damage and alteration of the channel strain and sheet height, outcomes that are generally undesirable in the sheet formation process.

In addition, the method may allow for more doping at the extension region. This increased doping can potentially address the junction underlapping issue and enhance the silicon etching rate. The dopant concentration, energy, dosage, tilt angle, and temperature may all be adjusted to achieve the desired results, providing a level of flexibility and control not commonly found in conventional methods.

The disclosure also provides several embodiments of the method, each with different doping strategies and potential outcomes. For instance, in some embodiments, the corners of the sheet may be doped to prevent DOI residual, while in others, the center may be doped to prevent over-etching. Other embodiments may involve different doping sequences and the use of a hard mask for Shallow Trench Isolation (STI) to prevent doping STI.

Overall, the method described in this disclosure provides a potential solution to the problem of residual material from the DOI process, offering a more efficient and precise approach to nano-FET formation using a DOI scheme.

Embodiments are described below in a particular context, a die comprising nano-FETs. Various embodiments may be applied, however, to dies comprising other types of transistors (e.g., stacking transistors, or the like) in lieu of or in combination with the nano-FETs.

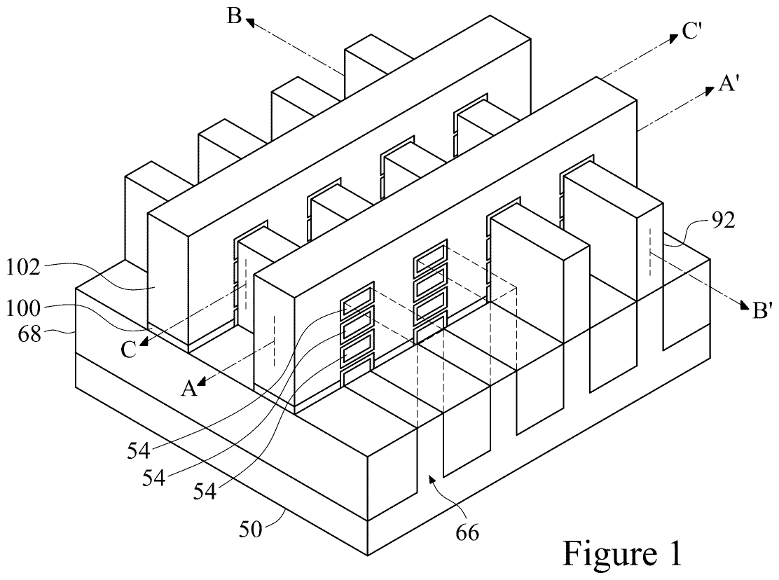

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. STI regions 68 (also referred to as STI structures or STI regions) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

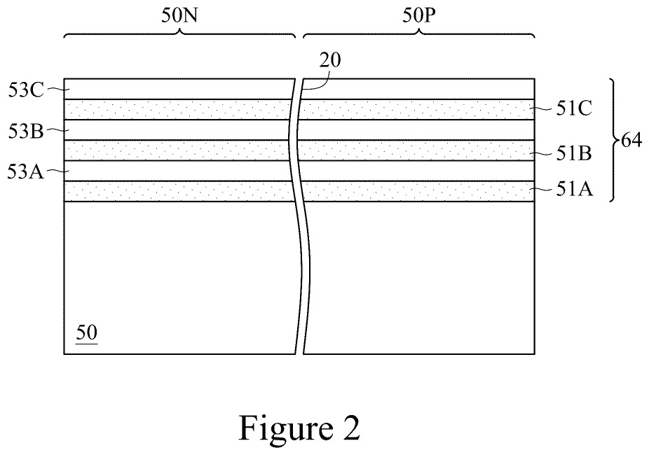

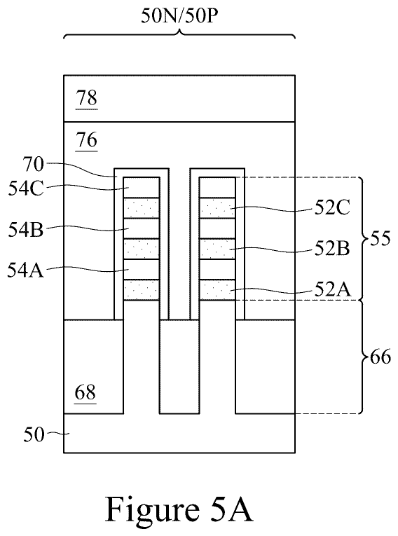

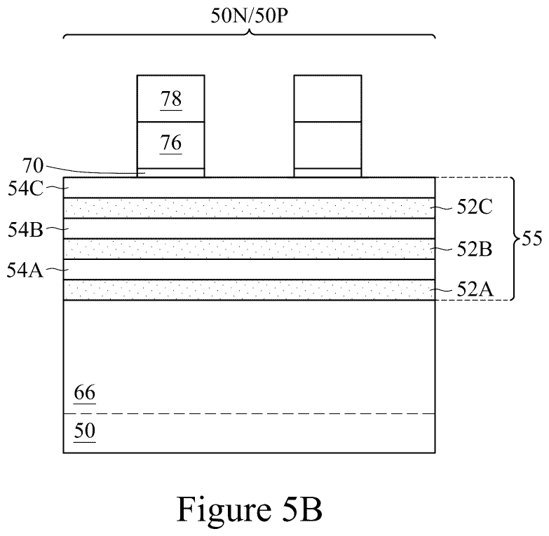

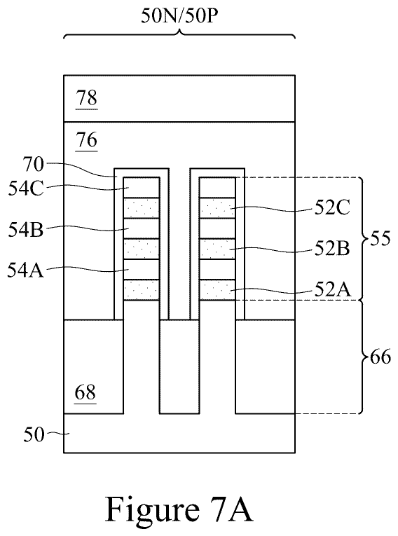

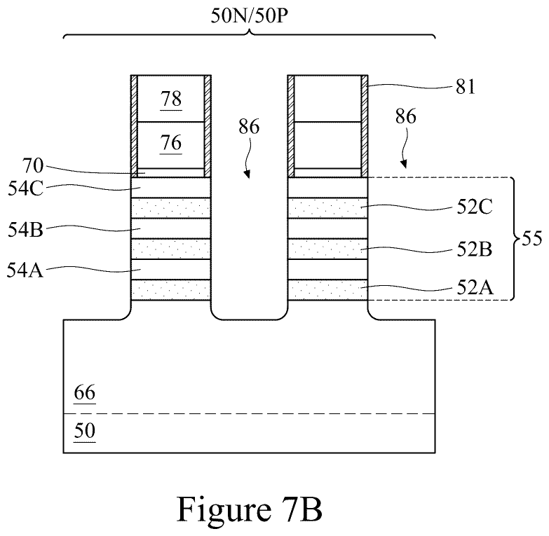

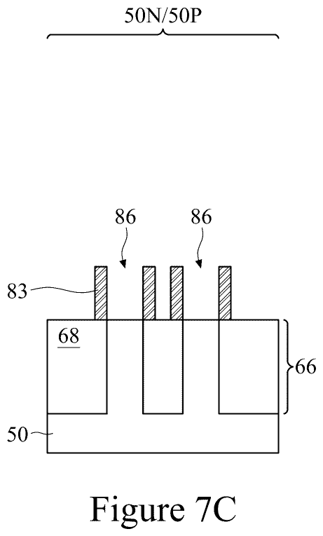

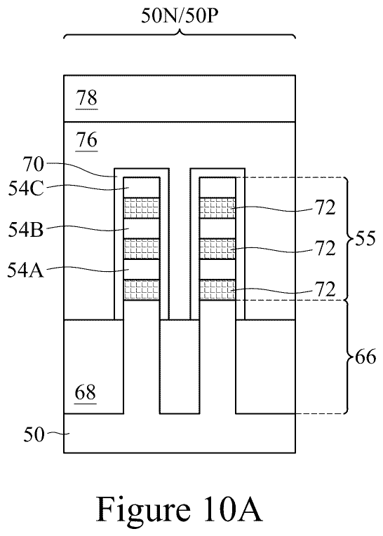

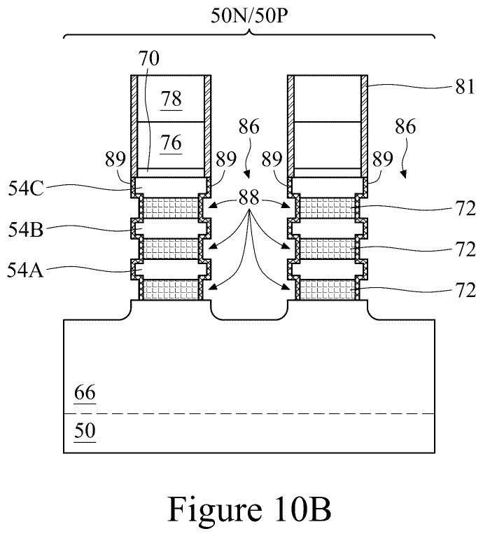

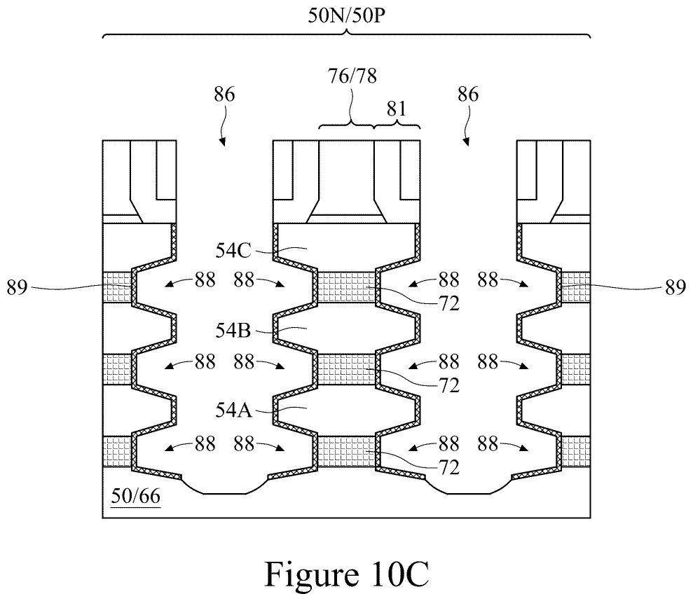

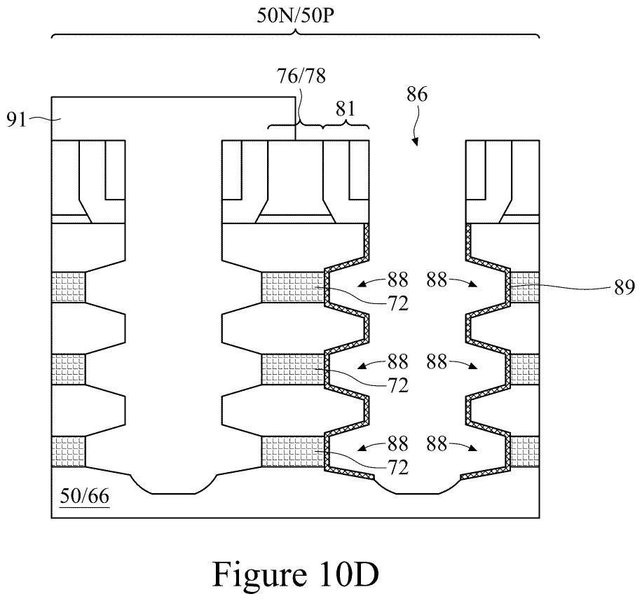

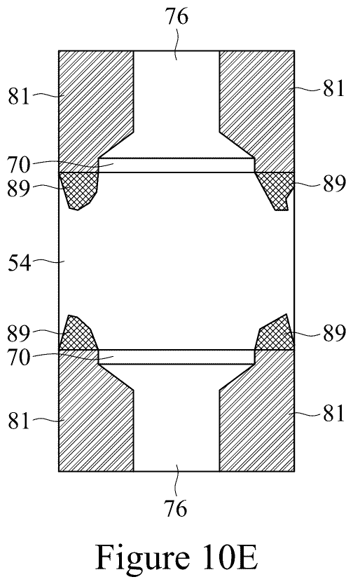

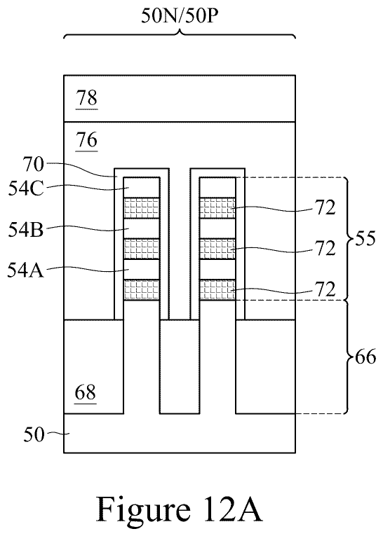

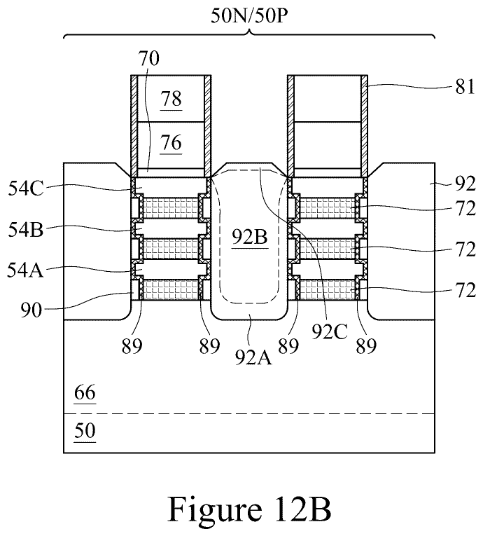

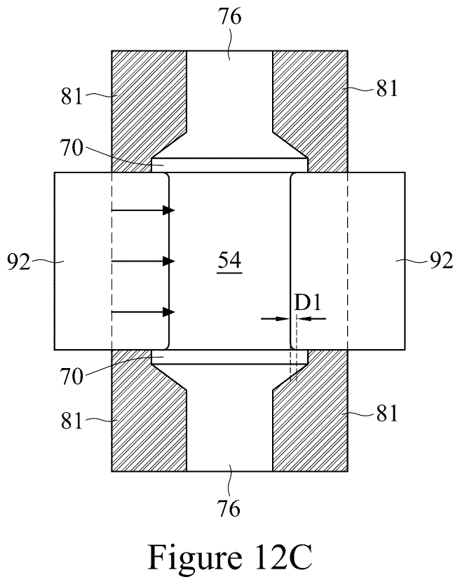

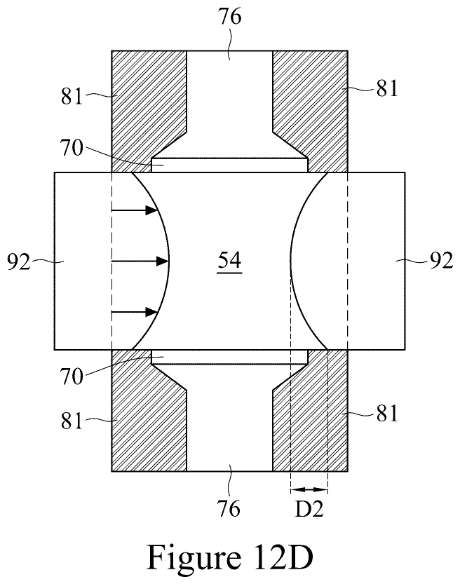

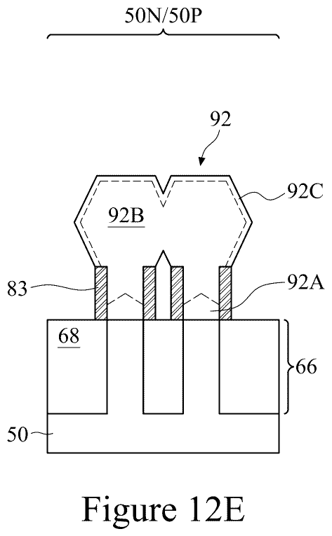

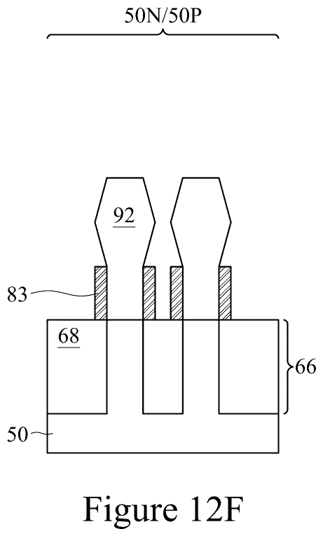

FIGS. 2 through 19C are cross-sectional views of intermediate stages in the manufacturing of nano-FETs, in accordance with some embodiments. FIGS. 2,3, 4, 5A, 6A, 7A, 8A, 9A, 10A, 11A, 12A, 13A, 14A, 15A, 16A, 17A, 18A, and 19A illustrate reference cross-section A-A′ illustrated in FIG. 1. FIGS. 5B, 6B, 7B, 8B, 9B, 9C, 10B, 10C, 10D, 11B, 12B, 13B, 14B, 15B, 16B, 17B, 18B, and 19B illustrate reference cross-section B-B′ illustrated in FIG. 1. FIGS. 7C, 12E, 12F, 17C, 18C, and 19C illustrate reference cross-section C-C′ illustrated in FIG. 1. FIGS. 10E, 12C, and 12D illustrate plan views of intermediate stages in the manufacturing of nano-FETs, in accordance with some embodiments.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or the another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

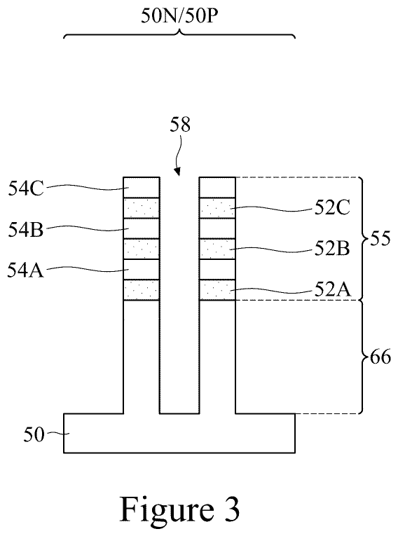

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask 56 may be used to define a pattern of the fins 66 and the nanostructures 55. The hard mask 56 may comprise any suitable insulating material, such as an oxide, a nitride, and oxynitride, and oxycarbonitride, or the like. In some embodiments (not separately illustrated), the hard mask 56 may be a multi-layer structure. The hard mask 56 may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

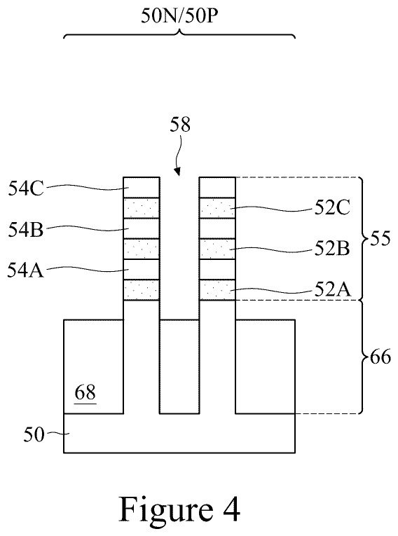

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates are formed over and along sidewalls of the nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68.

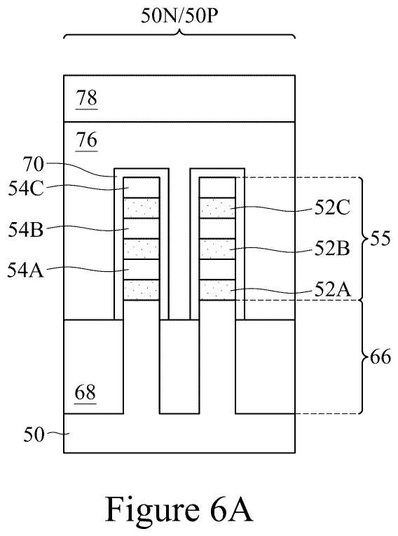

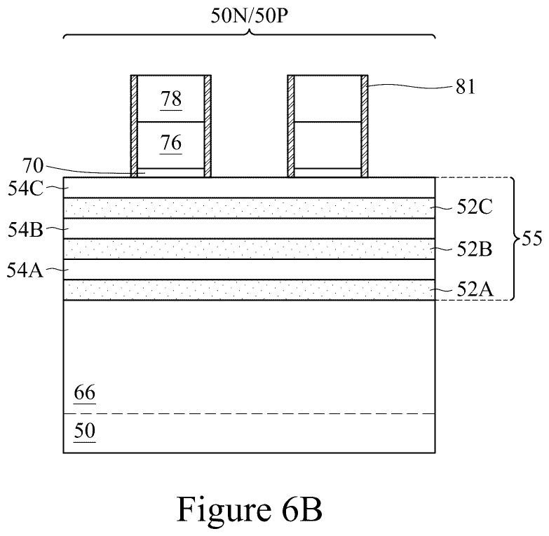

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

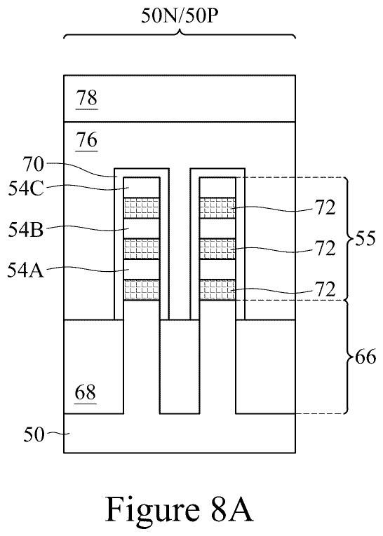

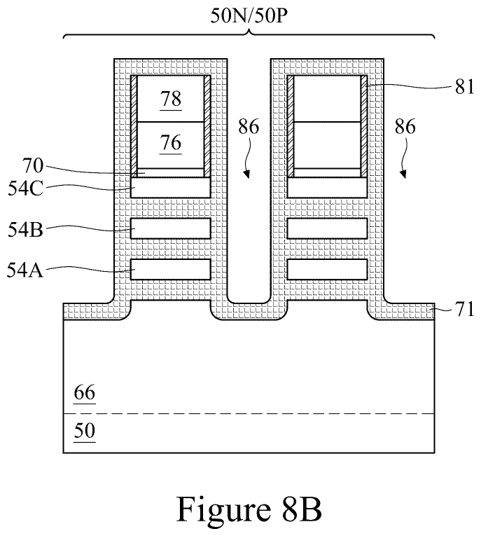

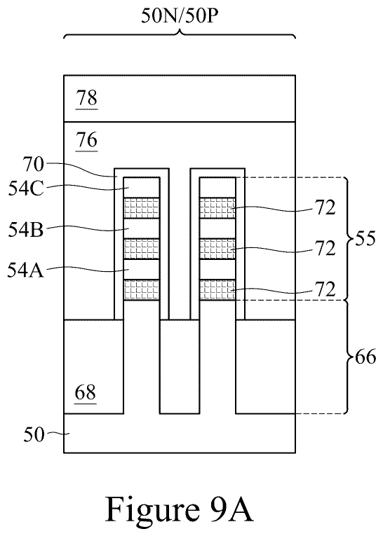

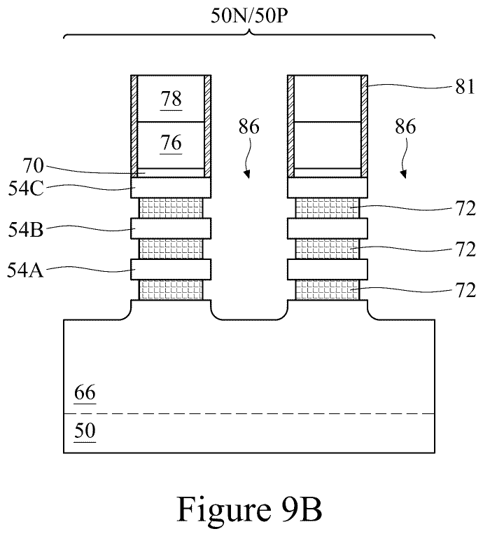

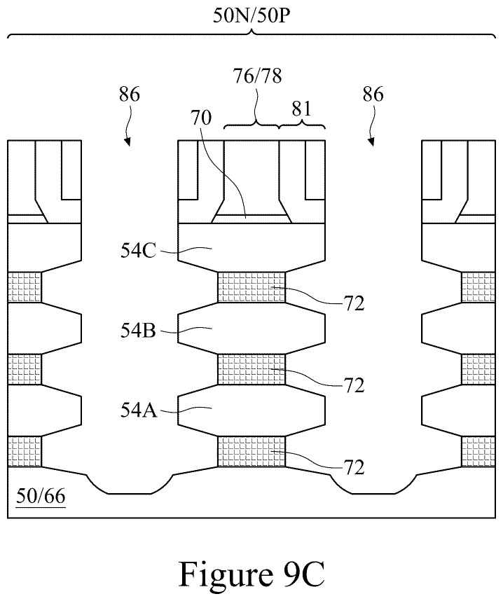

In FIGS. 8A-9C, the first nanostructures 52 are replaced with a sacrificial material 72 (also referred to as disposable interposers (DOI) 72). Replacing the first nanostructures 52 may include etching away the first nanostructures 52 using a suitable etch process, such as an isotropic etch process, that is performed through the first recesses 86 as illustrated by FIGS. 8A-8B. The etch process may be selective to the material of the first nanostructures 52 and remove the first nanostructures 52 without significantly removing the second nanostructures 54 or the fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

Subsequently, a sacrificial material layer 71 is deposited in the first recesses 86 and spaces where the first nanostructures 52 were removed. The sacrificial material layer 71 may be deposited by a conformal deposition process, such as CVD, ALD, or the like. The sacrificial material layer 71 may comprise an insulating material such as silicon oxide (e.g., SiO₂), silicon oxynitride, aluminum oxide, or the like that can be selectively etched from the second nanostructures 54.

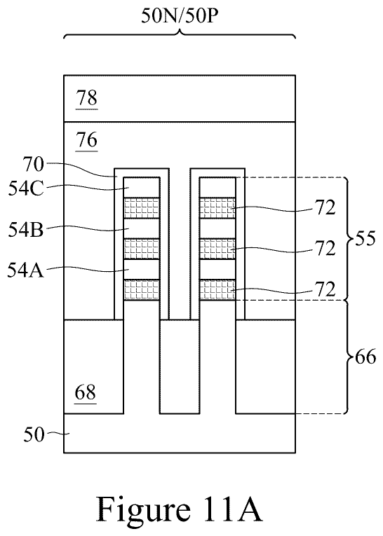

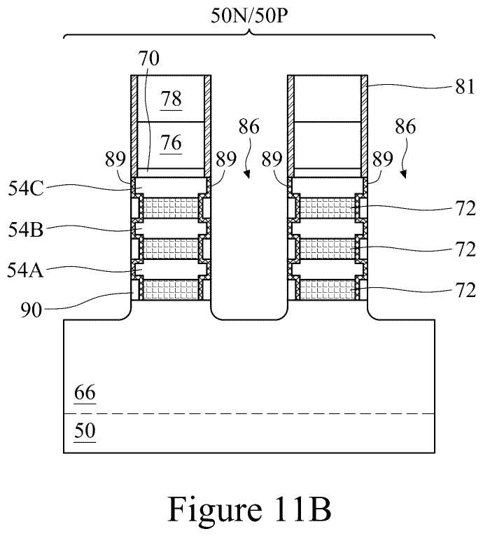

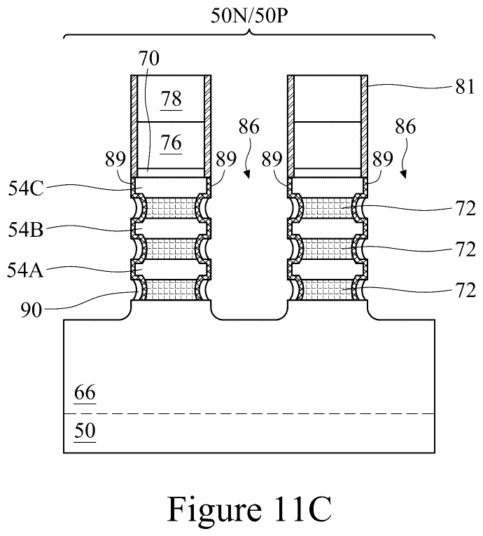

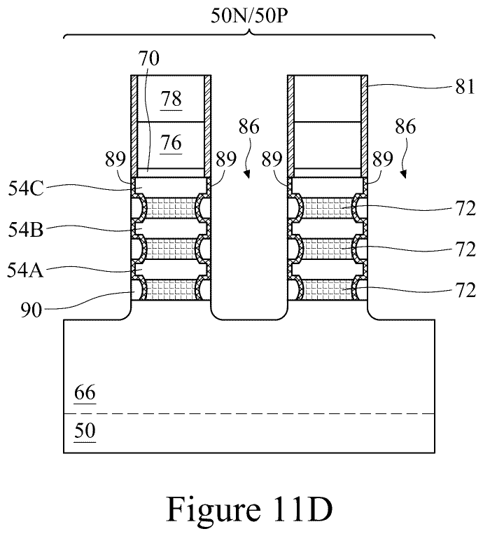

In FIGS. 9A-9C, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIGS. 9B and 9C, the sidewalls may be concave or convex (see e.g., FIG. 11C).

FIGS. 9B and 9C illustrate similar cross-sectional views in accordance with different embodiments. FIG. 9B illustrates a configuration of the structure that is similar to the previous figures showing nanostructures 54, gate structures 76/78, spacers 81, and sacrificial material 72 with planar surfaces and square corners. FIG. 9C on the other hand illustrates a configuration of the structure that shows the nanostructures 54, the gate structures 76/78, the spacers 81, and the sacrificial material 72 with non-planar surfaces and rounded corners. For example, FIG. 9C illustrate second nanostructures 54 that are thicker in the middle and thin towards the edges with rounded corners in the cross-sectional view. Further, FIG. 9C illustrates that the fins/substrate 66/50 exposed at the bottom of the recesses 86 has an indentation in the middle region of the recess 86. Also, the gate spacers 81 in FIG. 9C are illustrated as including multiple spacers layers. Although most of the figures in this disclosure illustrate the structures with planar surfaces and square corners, the scope of the disclosure is not limited thereto, as this disclosure also contemplates the structures having non-planar surfaces and rounded corner and profiles.

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 74, germanium residue may remain in channel regions of the resulting transistor devices, which negatively affects the performance of the channel regions. By replacing the first nanostructures 52 with an insulating material prior to the high-temperature processes (e.g., source/drain annealing), manufacturing defects can be reduced, and device performance can be improved (e.g., increased current drive, reduced capacitance, and improved short channel effect).

FIGS. 10A-D illustrate an implant process 88 forming doped regions 89 in the second nanostructures 54 and the sacrificial material 72 in the first recesses 86 to alter the etch rate of the structure. Similar to FIG. 9C above, FIGS. 10C and 10D illustrate embodiments of the structure with non-planar surfaces and rounded corners. The implant process 88 is designed to selectively modify the etch rate or etch selectivity of the second nanostructures 54 relative to the sacrificial material 72. This process may involve introducing implant species into the second nanostructures 54 and the sacrificial material 72 to create a differential etching characteristic that facilitates the subsequent removal of the sacrificial material 72 without adversely affecting the second nanostructures 54. The implant process 88 may be performed using a tilt implantation technique, where the implantation angle is controlled to optimize the distribution of the implant species within the target regions. In some embodiments, a mask 91 (see, e.g., FIG. 10D) is formed to cover one of the regions (either 50P or 50N) while the implant process 88 is performed on the other region. As illustrated in FIG. 10C, due to the non-planar surface of the fins/substrate 66/50 at the bottom of the recesses 86 and the tilt angle of the implant process 88, the doped regions 89 may not be continuous across the bottom of the recesses 86. In some embodiments, the doped regions 89 are not formed in the indentation at the bottom of the recesses 86.

In some embodiments, the implant process 88 may utilize n-type dopants, such as phosphorus, arsenic, or antimony, or other species like germanium, xenon, argon, silicon, or nitrogen, to enhance the etch rate of the sacrificial material 72. Alternatively, p-type dopants, such as boron, boron fluoride, indium or other species like carbon, may be used to retard the etch rate, thereby preventing over-etching of the sacrificial material 72. The choice of implant species may depend on the desired outcome of the etching process and the materials involved.

The implant process 88 may be characterized by a range of parameters that can be adjusted to achieve the desired modification of the etch rate or etch selectivity. The tilt angle of the implant may range from 0 degrees to 60 degrees, allowing for precise control over the implantation profile. The energy of the implant may be set between 1 keV to 50 keV, which, along with the dosage ranging from 5E¹³ to 1E¹⁶ atoms/cm², determines the depth and concentration of the implanted species. The temperature during the implant process 88 may be maintained within a range of −100° C. to 500° C. to accommodate various material properties and implantation outcomes.

In some embodiments, the implant process 88 may create an implant-induced damage layer on the sacrificial material 72, which can improve the efficiency of cleaning and etching during these processes. This enhancement can lead to increased etch selectivity, allowing for the complete removal of the sacrificial material 72 without leaving any residue and without causing damage to source/drain regions 92. As a result, the interface of the second nanostructures 54 can be smoother, which is beneficial for improved channel mobility in the semiconductor device.

By carefully selecting and controlling these parameters, the implant process 88 can be tailored to modify the etch rate or etch selectivity of the second nanostructures 54 and the sacrificial material 72 in a controlled manner. This enables a more efficient and precise etching process, reducing the likelihood of residual material and improving the overall quality of the semiconductor device.

The doped regions 89 in the second nanostructures 54 may be doped to a concentration ranging from approximately 1E¹⁸ to 1E¹⁹ atoms/cm³. This doping concentration is helps to control the shape of the second nanostructures during the subsequent etching process that removes the sacrificial material 72. Additionally, the dopant profile abruptness within this concentration range may be controlled to be within approximately 1 to 5 nm/decade, which is indicative of a sharp transition between doped and undoped regions.

The doped regions 89 in the sacrificial material 72 may be doped to a lower concentration compared to the second nanostructures 54, with a range from about 5E¹⁷ to 5E¹⁸ atoms/cm³. This concentration is selected to optimize the etch selectivity during the removal of the sacrificial material 72, ensuring that the second nanostructures 54 remain intact and undamaged. The dopant profile abruptness in the sacrificial material 72 is also controlled to facilitate a controlled etching process, contributing to the overall device fabrication efficiency.

In some embodiments the top second nanostructure 54C has a higher dopant concentration than the middle and lower second nanostructures 54B and 54A as the gate spacers 81 and overlying structures block some of the dopants during the implant process 88. As seen in FIGS. 10B and 10C, the top second nanostructure 54C has doped region 89 formed on two surfaces (e.g., side and lower surfaces) while the middle and lower second nanostructures 54B and 54A have doped regions 89 formed on three surfaces (e.g., upper, side, and lower surfaces).

The adjustment of dopant concentrations and profile abruptness in both the second nanostructures 54 and the sacrificial material 72 enhances the etching process and ensures the formation of a semiconductor device with improved channel mobility and reduced electrical resistance. This approach allows for the precise tailoring of the semiconductor device characteristics to meet specific performance requirements.

FIG. 10E illustrates a plan view of a second nanostructure 54 with doped regions 89 within the second nanostructure 54 in accordance with some embodiments. The doped regions 89 are configured to modify the etch rate of the second nanostructures 54, which is a strategic step in the fabrication process. The implant process 88 introduces dopants into the second nanostructures 54 in a manner that creates a differential etching characteristic between the second nanostructures 54 and the sacrificial material 72. This differential etching characteristic is advantageous for the subsequent removal of the sacrificial material 72, as it allows for the selective etching of the sacrificial material 72 without adversely affecting the second nanostructures 54.

The configuration of the doped regions 89 is such that it can be tailored to the specific requirements of the semiconductor device being fabricated. By adjusting the parameters of the implant process 88, such as the tilt angle, energy, dosage, and temperature, the etch rate or etch selectivity of the second nanostructures 54 can be controlled.

Although the doped regions 89 are illustrated with well-defined boundaries in subsequent figures, in some embodiments, the boundaries of doped regions 89 are more gradual and may move or change from dispersion of the dopants due to further processing such as thermal processes, etch process, or the like.

In FIGS. 11A and 11B, inner spacers 90 are formed in the first recesses 86 on the sidewalls of the sacrificial material 72 and/or the doped regions 89. The inner spacers 90 act as isolation features between subsequently formed source/drain regions and a gate structure. As will be discussed in greater detail below, source/drain regions will be formed in the first recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 10A and 10B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54 (see e.g., FIG. 11C). Moreover, although the outer sidewalls of the inner spacers 90 are illustrated as being straight in FIG. 11B, the outer sidewalls of the inner spacers 90 may be concave or convex. As an example, FIG. 11C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 11D illustrates an embodiment in which sidewalls of the sacrificial material 72 are concave, outer sidewalls of the inner spacers 90 are straight, and the inner spacers 90 are flush with sidewalls of the second nanostructures 54.

In FIGS. 12A-12F, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated in FIG. 12B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as Si, SiP, SiAs, SiP+SiAs/SiSb, SiSb, SiP+SiAs+SiSb, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as SiGe, Ge, GeSn, SiB, SiGe: B, SiGe: Ga, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

FIG. 12C illustrates a plan view of a second nanostructure 54 and epitaxial source/drain regions 92 in accordance with some embodiments. In some embodiments, the wafer is tilted during the implant process 88, which allows for selective doping of the corners of the second nanostructure 54 which can be advantageous to prevent the residual sacrificial material 72 in the subsequent removal of the sacrificial material 72. In some embodiments, not only the corners (see, e.g., FIG. 10E) but the entire sides (including the middle regions in addition to the corners) of the second nanostructure 54 may be doped which can be advantageous to prevent over-etching. This selective doping results in a tailored dopant distribution that can be used to modify the etch rate of the second nanostructures 54, thereby enhancing the etching process and improving the overall device performance. For example, using this control of the etch rate, the rounding of the sides of the second nanostructure 54 can configured. In FIG. 12C, the rounding of the sides of the second nanostructure 54 is illustrated by a distance D1 which is the difference between the innermost and outermost points of the side of the second nanostructure 54 in this plan view. In some embodiments, the distance D1 in this configuration is less than 1 nm. This configuration is beneficial for achieving a smooth interface between the second nanostructure 54 and the epitaxial source/drain regions 92, which is desirable for better junction uniformity and device performance.

FIG. 12D illustrates a plan view of a second nanostructure 54 and epitaxial source/drain regions 92 in accordance with some embodiments. In this embodiment, the wafer is not tilted during the implant process 88, resulting in a uniform dopant distribution across the entire sides (e.g., from top corner to bottom corner on both sides) of the second nanostructure 54. The uniform distribution of dopants leads to a curved profile between the second nanostructure 54 and the epitaxial source/drain regions 92 due to the faster etching rate at the center than at the edge. In FIG. 12D, the rounding of the sides of the second nanostructure 54 is illustrated by a distance D2 which is the difference between the innermost and outermost points of the side of the second nanostructure 54 in this plan view. In some embodiments, the distance D2 in this configuration is 3 nm or greater.

Using various implant species enables not just the enhancement of etching rates for the sacrificial material 72 and the second nanostructures 54 but also the deepening of the junction. The dopant concentration within the sacrificial material 72 is at a lower level relative to that within the source/drain regions 92. During the formation of the source/drain regions 92, the implantation process can introduce defects into these regions, which may promote the diffusion of dopants from the source/drain regions 92 into the adjacent channel areas. This diffusion of dopants can result in a decrease in the electrical resistance of the channels of the subsequently formed transistor structure.

In the tilt implant embodiment, the distribution of doped regions 89 can be selectively controlled. For instance, the STI regions 68, the fins 66, and the lower portions of the second nanostructures 54, as well as the sacrificial material 72, may remain undoped while upper portions of the structure are doped. Consequently, varying dopant concentrations can be achieved across different layers of the second nanostructures 54. For example, in a configuration with three layers of second nanostructures 54, an initial implant process 88 may introduce dopants into all three layers, while a subsequent implant process 88 may target just the upper two layers. Various other sequences of doping are also feasible. Additionally, the gate spacers 81, which are adjacent to the dummy gates 76, may be subjected to doping. This doping can potentially reduce the dielectric constant (k value) of the gate spacers 81, which may also lead to a reduction in electrical leakage.

In the plasma doping embodiment, the STI regions 68, the fins 66, the gate spacers 81 adjacent to the dummy gates 76, the second nanostructures 54, and the sacrificial material 72 are all subjected to doping during the implant process 88. When doping reaches the bottom portion of the fins 66, it may influence the growth of the source/drain regions 92 from the bottom up. For instance, the introduction of dopants can potentially damage the crystal lattice, which might degrade the quality of the epitaxial source/drain regions 92.

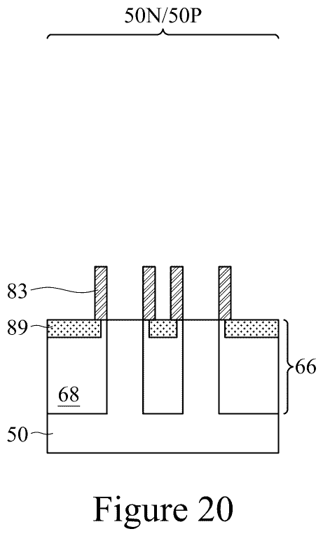

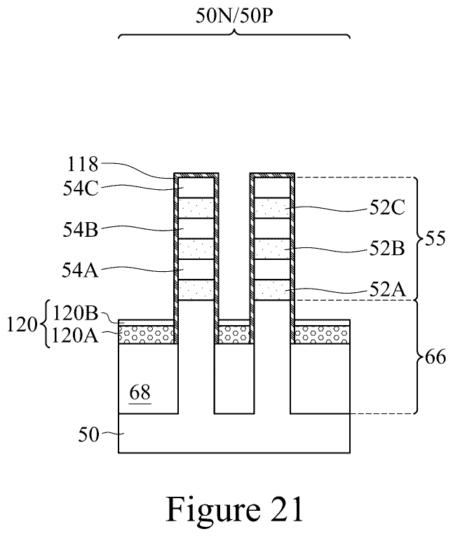

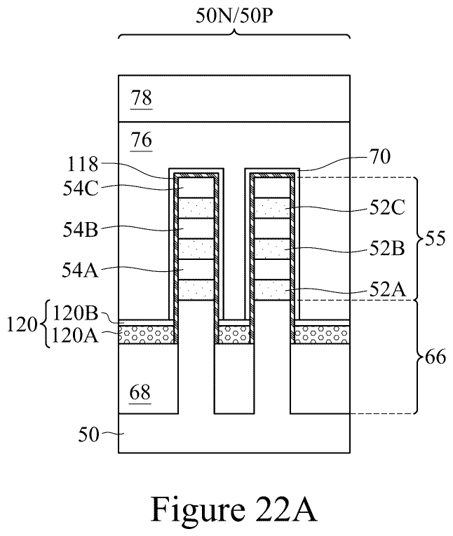

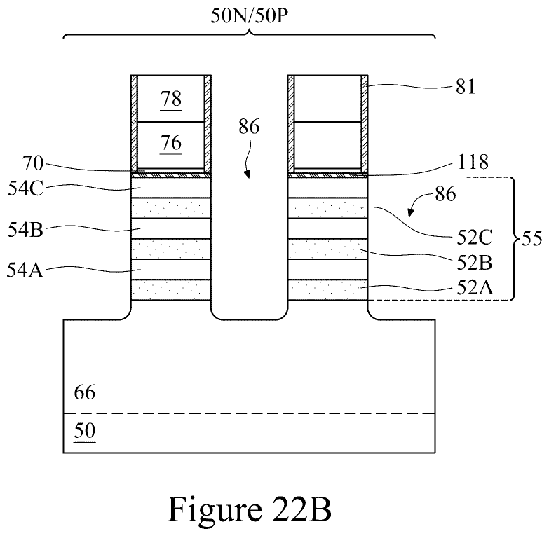

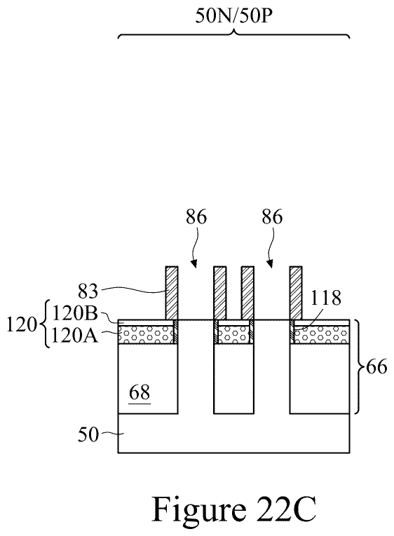

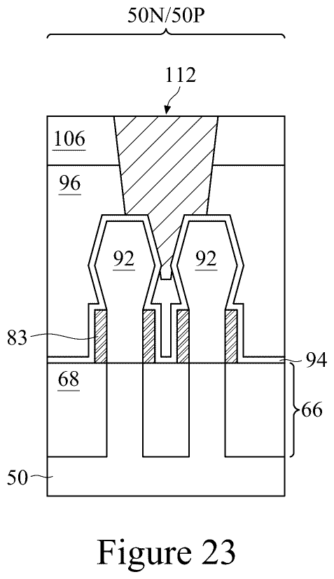

Additionally, when the STI regions 68 are doped, the etching rate of the STI regions 68 during subsequent etching processes can be modulated (see, e.g., FIG. 20). Consequently, this allows for the adjustment of the height of the top surface of the STI regions 68, as further discussed in relation to FIG. 20. To prevent doping of the STI regions 68, an optional hard mask structure, as depicted in FIGS. 21-22C, can be employed.

The doped regions 89 formed by the implant process 88, particularly at the source/drain extension region adjacent to the second nanostructures 54, can enhance the etch rate of these structures. This enhancement facilitates the modulation of the convex push amount of source/drain regions 92 into channel regions (e.g., second nanostructures 54), which is a technique used for controlling the short channel effects in semiconductor devices. By adjusting the dopant distribution, the shape of the interface between the second nanostructures 54 and the source/drain regions 92 can be finely tuned, contributing to improved device performance.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12E. In other embodiments, adjacent epitaxial source/drain regions 92 remain separated after the epitaxy process is completed as illustrated by FIG. 12F. In the embodiments illustrated in FIGS. 12E and 12F, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI regions 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

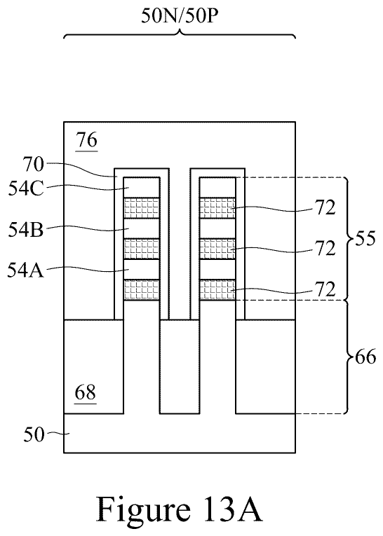

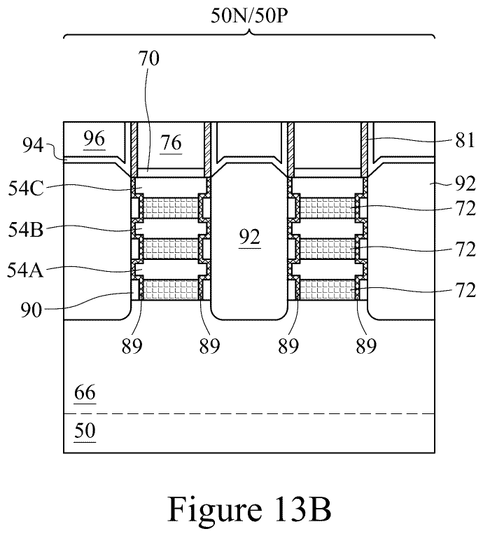

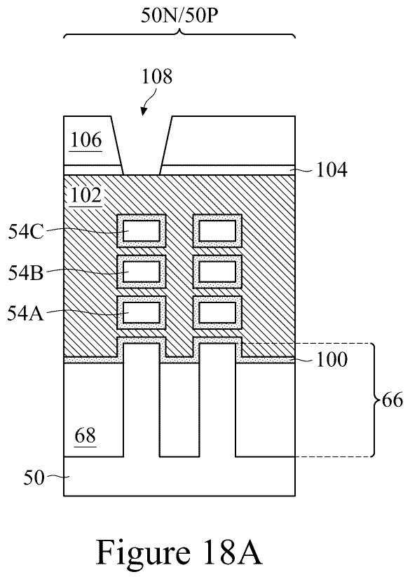

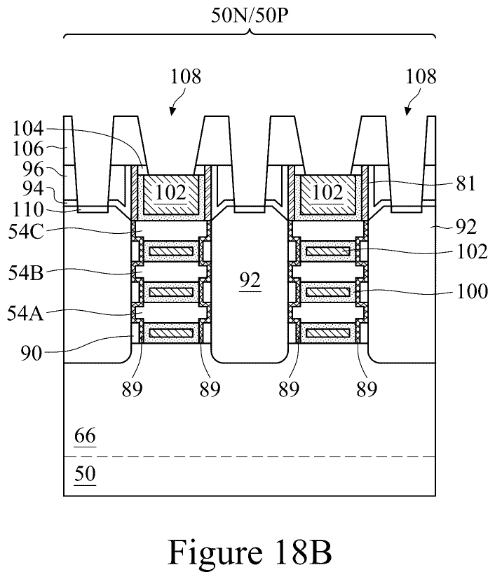

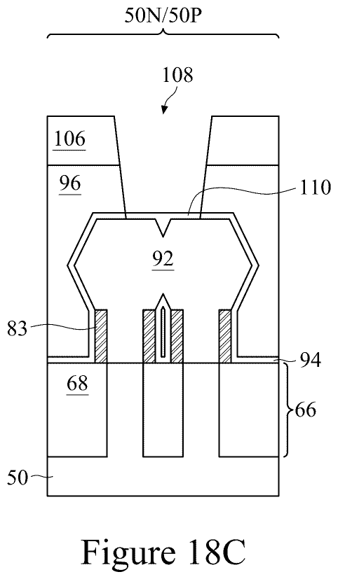

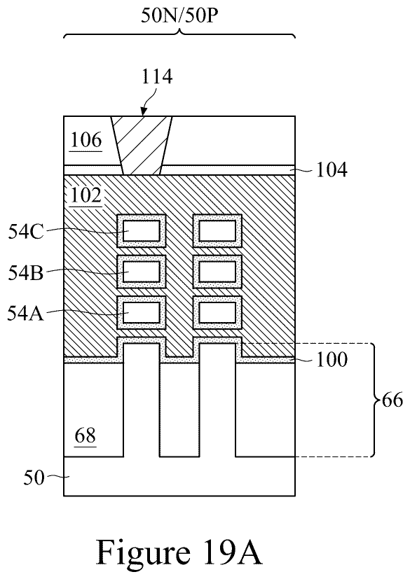

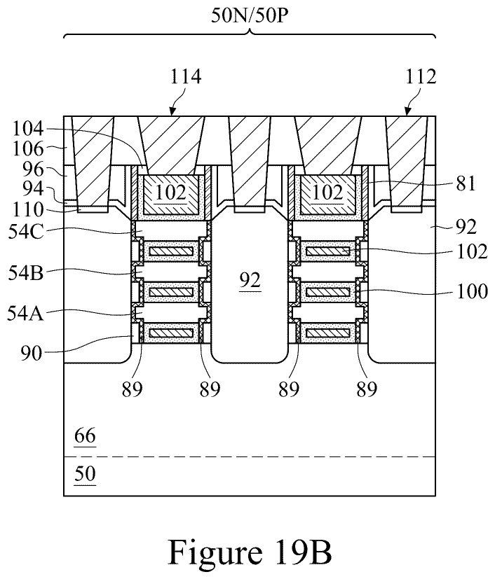

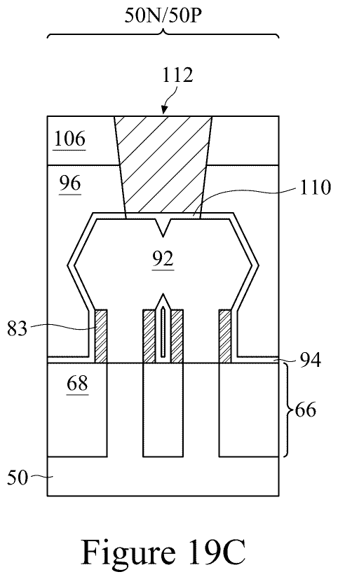

In FIGS. 13A and 13B, a first interlayer dielectric (ILD) 96 is deposited over the structure illustrated in FIGS. 18A and 19B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

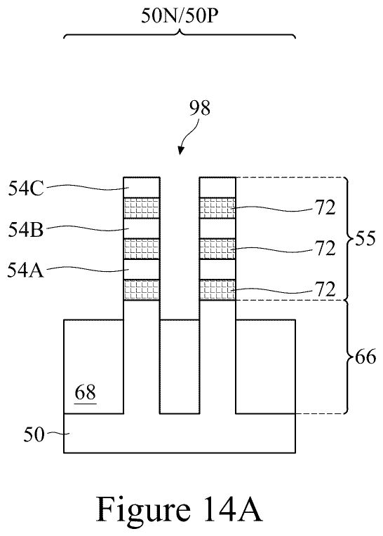

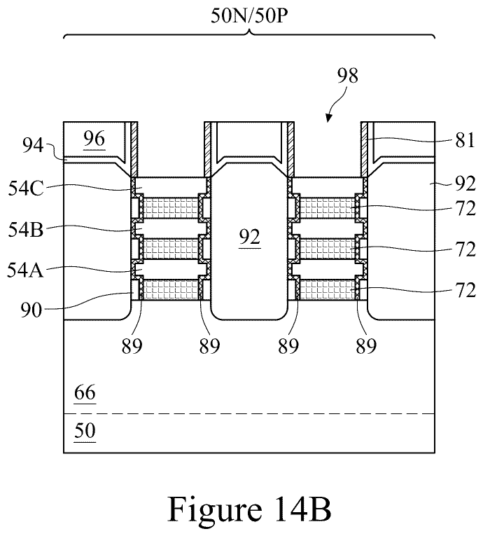

In FIGS. 14A and 14B, the dummy gates 76, and the masks 78 if present, are removed in one or more etching steps, so that second recesses 98 are formed. Portions of the dummy gate dielectrics 70 and portions of the protective liner 118 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

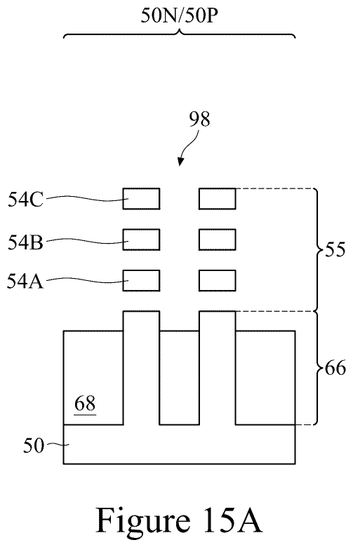

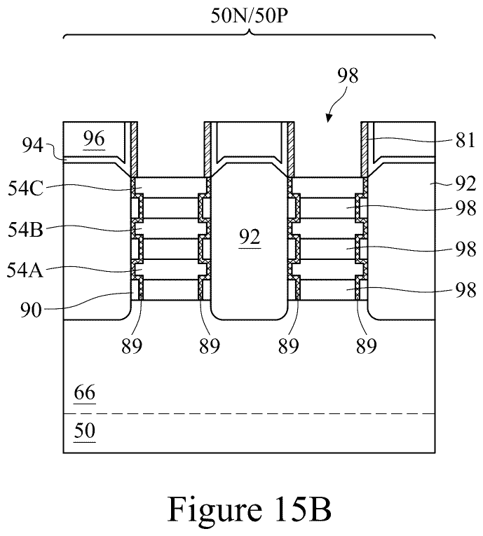

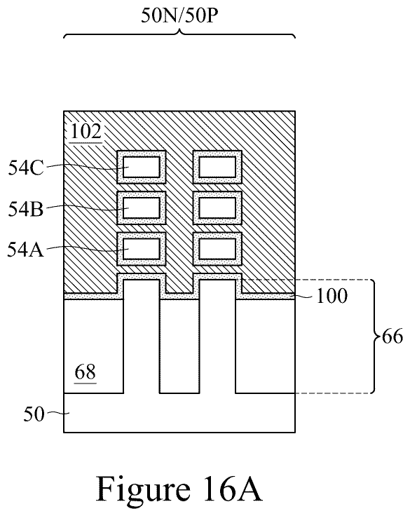

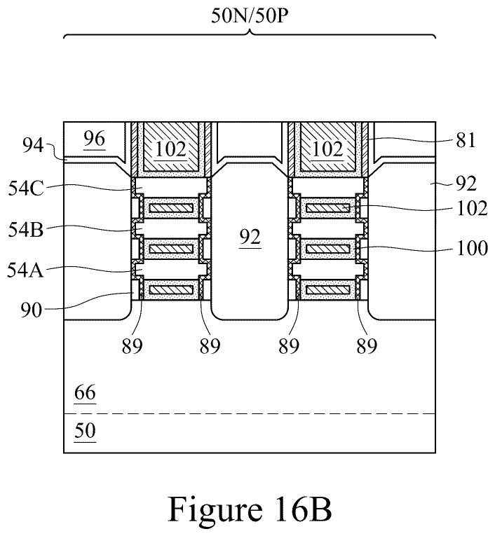

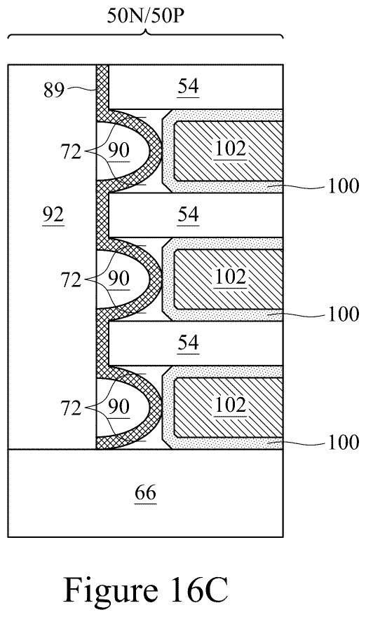

In FIGS. 15A and 15B, the sacrificial material 72 is removed, which extends the second recesses 98. In some embodiments, the removal of the sacrificial material 72 removes portions of the doped regions 89 in or adjacent the sacrificial material. The removal of the sacrificial material 72 may involve an isotropic etching process, such as a wet etching using dilute hydrofluoric acid (HF) or a chemical oxide removal (COR) dry etch. These etchants are selective to the materials of the sacrificial material 72, ensuring that the second nanostructures 54 remain relatively unetched in comparison to the sacrificial material 72. The sacrificial material 72 may be completely removed, or a residue of the sacrificial material 72 may remain on sidewalls of the inner spacers in the second recesses 98 (see e.g., FIG. 16C).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (see, e.g., FIGS. 21-22C) at a top surface to protect the underlying STI regions 68 from etching while patterning and removing the sacrificial material 72. In such embodiments, the hard mask may comprise, for example, a nitride.

The residual dopants from the implant process 88 that remain in the second nanostructures 54 after the etching process (e.g., after etching of FIGS. 15A-B) can serve to reduce the electrical resistance of the channel. This reduction in resistance is beneficial for the overall electrical performance of the device, as it can lead to increased current flow and improved switching characteristics of the transistors. The precise control over dopant concentration and distribution is thus a valuable tool in the optimization of semiconductor device fabrication.

In FIGS. 16A-16C, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 16A-16C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 16C illustrates a detailed view of various elements of FIG. 16B, including the epitaxial source/drain regions 92, the gate dielectric layers 100, the gate electrodes 102, the second nanostructures 54, and the inner spacers 90. In some embodiments, illustrated by FIG. 15C, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

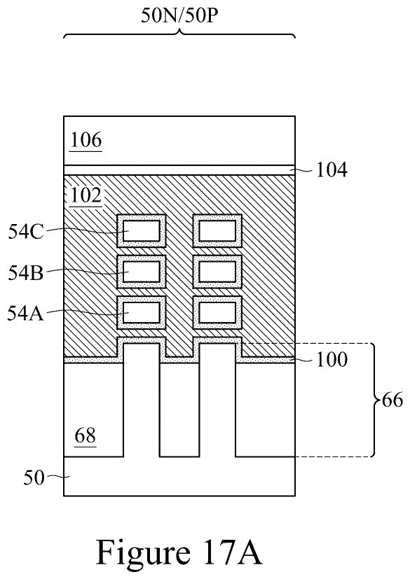

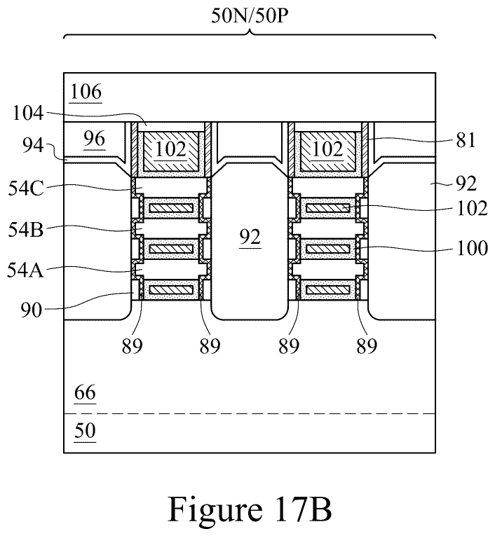

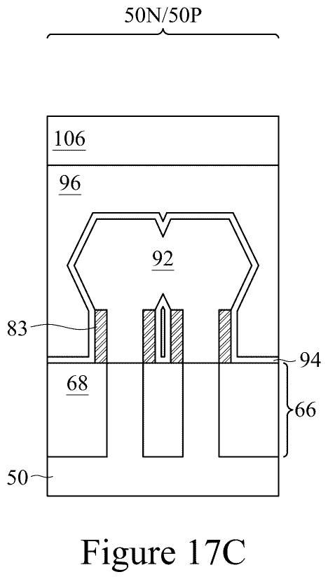

In FIGS. 17A-17C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 19A-19C) penetrate through the gate mask 104 to contact the top surface of the recessed gate electrodes 102.

As further illustrated by FIGS. 17A-17C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 18A-18C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 18B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 19A-19C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts 114, and the contacts 112 are electrically coupled to the silicide regions 110 and may be referred to as source/drain contacts 112. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

FIG. 20 illustrates a cross-sectional view of an intermediary step of manufacturing a nano-FET transistor, in accordance with some embodiments. FIG. 20 illustrates reference cross-section C-C′ illustrated in FIG. 1. In FIG. 20, like reference numerals indicate like elements formed by like processes as described above in FIGS. 2 through 19C unless otherwise indicated. FIG. 20 illustrates a similar step in processing as FIGS. 10A-C and the description is not repeated herein.

In this embodiment, the implant process 88 also forms doped regions 89 within the upper surface of the STI regions 68. This allows for the modification of the etching rate of the STI during subsequent etching and patterning steps (e.g., etching of inner spacers or removal of sacrificial material 72). By adjusting the etching rate, the height of the top surface of the STI can be controlled.

The doped regions 89 in the STI regions 68 can be formed simultaneously with the doped regions in the second nanostructures 54 and the sacrificial material 72. The type and concentration of the dopants, as well as the implantation conditions, can be controlled to achieve the desired modification of the etching rate.

The ability to adjust the height of the STI top surface can have several benefits. For instance, it can help in achieving a more uniform device structure, which can lead to improved device performance. It can also help in reducing manufacturing defects and enhancing the overall yield of the manufacturing process. Furthermore, the ability to control the STI height can provide flexibility in the design and fabrication of the semiconductor device, allowing for the tailoring of the device characteristics to meet specific performance requirements.

FIGS. 20-C illustrate cross-sectional views of intermediary steps of manufacturing a nano-FET transistor, in accordance with some embodiments. FIG. 21 illustrates reference cross-section C-C′ illustrated in FIG. 1. FIG. 22A illustrates reference cross-section A-A′ illustrated in FIG. 1. FIG. 22B illustrates reference cross-section B-B′ illustrated in FIG. 1. FIG. 22C illustrates reference cross-section C-C′ illustrated in FIG. 1. In FIGS. 20-21C, like reference numerals indicate like elements formed by like processes as described above in FIGS. 2 through 19C unless otherwise indicated.

In this embodiment, hard mask layers may be formed on a top surface of the STI regions 68 to reduce isolation region loss during subsequent cleaning and/or etching processes that are performed to fabricate the transistor. FIG. 21 illustrates a similar step in processing as FIG. 4 and the description is not repeated herein. FIGS. 22A-C illustrates a similar step in processing as FIGS. 7A-C and the description is not repeated herein.

As illustrated in FIG. 21, a hard mask structure 120 is formed on the top surface of the STI regions 68. In some embodiments, the hard mask structure 120 is a multi-layer structure comprising, for example, a nitride hard mask and a silicon hard mask over the nitride hard mask. In some embodiments, an optional protective liner 118 is deposited over and along sidewalls of the nanostructures 55 and on exposed upper sidewalls of the fins 66 before the formation of the hard mask structure 120.

For example, the optional protective liner 118 may be formed after the STI regions 68 and before the dummy gates are formed. In some embodiments, the protective liner 118 is made by growing a silicon layer using an epitaxial process, such as, CVD, ALD, VPE, MBE, or the like. In some embodiments, the protective liner 118 is selectively deposited on a semiconductor material of the nanostructures 55 and the fin 66 without being deposited on the exposed surfaces of the STI regions 68. The deposition process used to form the protective liner 118 may allow a relatively high-quality material to be formed. For example, when the protective liner 118 is a silicon layer that is deposited by an ALD process, the protective liner 118 may have improved coverage and be more crystalline than the second nanostructures 54. The higher quality material of the protective liner 118 may be more resistant to etching and reduce undesired thinning of the second nanostructures 54 during subsequent processing steps. As a result, the protective liner 118 may allow for higher quality channel regions to be formed in the resulting device. The protective liner 118 may be omitted in some embodiments.

After the formation of the optional protective liner 118 and before the dummy gates are formed, a first hard mask 120A is deposited over and along sidewalls of the nanostructures 55, on the upper sidewalls of the fins 66, and on the upper surfaces of the STI regions 68. The first hard mask 120A may be a nitride layer, such as a silicon nitride layer, a silicon oxynitride layer, a silicon oxycarbonitride layer, or the like. A nitrogen concentration of the first hard mask 120A may be greater than a nitrogen concentration of the STI regions 68. In some embodiments, the first hard mask 120A is deposited by a non-conformal deposition process, such as, a plasma enhanced CVD (PECVD) process or the like. The non-conformal deposition process may form sidewalls portions of the first hard mask 120A to have a thickness that is less a thickness of lateral portions of first hard mask 120A. The non-conformal deposition process may aid in the patterning and selective removal of the sidewall portions of the first hard mask 120A.

The upper and sidewall portions of the first hard mask 120A may be removed before the second hard mask 120B is formed. The upper portions of the first hard mask 120A may include lateral portions of the first hard mask 120A that are disposed above the nanostructures 55. Removing the upper portions of the first hard mask 120A may include depositing a mask layer (not shown) over the first hard mask 120A followed by one or more etching processes may to remove the upper portions of the first hard mask 120A. Removing the sidewall portions of the first hard mask 120A may include an etching process, such as an isotropic etching process.

Further, a second hard mask 120B is deposited over the first hard mask 120A. The second hard mask 120B may be deposited over top surfaces of the nanostructures 55, along sidewalls of the nanostructures 55, and over upper surfaces of the first hard mask 120A. The second hard mask 120B may be formed of a material with a higher etch selectivity to the STI regions 68 than the first hard mask 120A relative a same etch process. In some embodiments, the second hard mask 120B is a semiconductor material. For example, the second hard mask 120B may be made of silicon, or the like when the first hard mask 120A is made of a nitride material and the STI regions 68 are made of an oxide material.

The second hard mask 120B may be formed of a non-conformal deposition process, such as an FCVD process. An annealing process may be performed once the second hard mask 120B is formed. Further, the non-conformal deposition process may deposit a lower quality material than the material of the protective liner 118. For example, compared to the protective liner 118, the second hard mask 120B may have worse coverage, particularly on sidewalls and upper surfaces of the nanostructures 55, as well as be less crystalline. As a result, the second hard mask 120B may be more 1 readily etched away in subsequent processes than the protective liner 118. Other non-conformal deposition processes, such as a PECVD process, may be used in other embodiments to deposit the second hard mask 120B.

Subsequently, the sidewall portions and upper portions of the second hard mask 120B are removed while bottom portions of the second hard mask 120B remains (see FIGS. 20-21C). Removing the sidewall portions and the upper portions of the second hard mask 120B may include an etching process, such as an isotropic etching process. The optional protective liner 118 may be removed during the replacement gate process.

The hard mask structure 120 has a multi-layer structure that comprises the first hard mask 120A (e.g., a nitride) and the second hard mask 120B (e.g., a silicon hard mask). The hard mask structure 120 protects the underlying STI regions 68 during subsequent processing steps (e.g., subsequent etching and/or cleaning processes). Further, by including a combination of materials in the first hard mask 120A and the second hard mask 120B, parasitic capacitance in the resulting device can be reduced.

FIG. 22 illustrate cross-sectional views of an intermediary step of manufacturing a nano-FET transistor, in accordance with some embodiments. FIG. 22 illustrates reference cross-section C-C′ illustrated in FIG. 1. In FIG. 22, like reference numerals indicate like elements formed by like processes as described above in FIGS. 2 through 19C unless otherwise indicated. FIG. 22 illustrates a similar step in processing as FIGS. 19A-C and the description is not repeated herein.

In this embodiment, the adjacent epitaxial source/drain regions 92 remain separated after the epitaxy process is completed (similar to FIG. 12F) and the source/drain contacts 112 may extend between the adjacent epitaxial source/drain regions 92 to have a bottom surface lower than the top surface of the epitaxial source/drain regions 92. Although the contacts 112 are shown extending between the adjacent epitaxial source/drain regions 92 into the STI regions 68, using the embodiments of the current disclosure, the contacts 112 may not extend as far as conventional devices as the removal and loss of the STI regions 68 is reduced with the current disclosure. This can improve the yield and reduce the parasitic capacitance in the resulting device.

The disclosed method offers an approach to nano-FET formation in semiconductor manufacturing that addresses challenges such as the occurrence of residual oxide after the removal of the Disposable Oxide Interposer (DOI) and the issue of over-etching during the DOI oxide etching process. By using a tilt implant or plasma doping technique, the method increases the etching rate of the DOI, which helps to minimize the presence of residual oxide and reduces the likelihood of source/drain epitaxial damage and changes in channel strain and sheet height.

The method also allows for increased doping at the extension region, which can address the junction underlapping issue and improve the silicon etching rate. This control over doping enhances the interface between the sheets and the source/drain regions, potentially leading to better channel mobility and device performance. The dopant distribution can be selectively adjusted in specific areas, such as the corners or center of the nanostructure, to modulate the etch rate and dopant profile.

This method is adaptable to various doping strategies and outcomes, which can be customized based on manufacturing requirements. It allows for the control of dopant concentrations across different layers of the nanostructures, which can be adjusted through multi-tilt implant condition design. Additionally, the method may reduce the dielectric constant of adjacent gate spacers, which could decrease electrical leakage and improve device reliability.

In conclusion, the method provides an approach to semiconductor nano-FET formation that enhances efficiency and precision, offering a solution that addresses some of the limitations found in previous methods. It allows for the adjustment of etching rates and dopant profiles, which can reduce the risks associated with residual materials and over-etching, making it a useful technique in the production of semiconductor devices.

In an embodiment, a method may include forming a multi-layer stack over a substrate. The multi-layer stack has alternating layers of first semiconductor layers and second semiconductor layers. The method may also include removing the first semiconductor layers. Furthermore, the method may include forming a disposable material between the second semiconductor layers. In addition, the method may include performing a first implantation process on the disposable material and the second semiconductor layers. Moreover, the method may include forming source/drain regions adjacent to the second semiconductor layers and the disposable material. The method may also include replacing the disposable material with a metal gate structure.

The described embodiments may also include one or more of the following features. The method may use a disposable material selected from the group of silicon oxide, silicon oxynitride, and aluminum oxide. Additionally, the method may include performing a second implantation process to introduce n-type dopants into the source/drain regions after forming the disposable material between the second semiconductor layers. The first implantation process on the disposable material and the second semiconductor layers may include a tilt implantation process. The first implantation process may include a plasma. The method may use phosphorus, arsenic, or antimony, germanium, xenon, argon, silicon, nitrogen, boron, boron fluoride, indium, and carbon for the first implantation process on the disposable material and the second semiconductor layers. The first implantation process on the disposable material and the second semiconductor layers may change etch selectivity between the second semiconductor layers and the disposable material. The method of replacing the disposable material with the metal gate structure may further include removing the disposable material using an etching process that is selective to the disposable material over the second semiconductor layers. The method may include forming inner spacers on the sidewalls of the disposable material after performing the first implantation process. The inner spacers may include silicon nitride, silicon oxynitride, or a combination thereof. The inner spacers may have a convex shape facing the disposable material.

In an embodiment, a method may include forming a multi-layer stack over a substrate. The multi-layer stack has alternating layers of first semiconductor layers and second semiconductor layers. The method may also include patterning the multi-layer stack to define a fin. Furthermore, the method may include forming a recess adjacent to the fin. In addition, the method may include selectively removing the first semiconductor layers. Moreover, the method may include forming a sacrificial material between the second semiconductor layers. The method may also include performing a doping process on the sacrificial material and the second semiconductor layers to alter etch selectivity. Furthermore, the method may include growing epitaxial source/drain regions in the recess adjacent to the second semiconductor layers. The method may also include replacing the sacrificial material with a metal gate structure.

The described embodiments may also include one or more of the following features. The doping process may include introducing dopants such as phosphorus, arsenic, or antimony, germanium, xenon, argon, silicon, nitrogen, boron, boron fluoride, indium, and carbon. The sacrificial material may include a material selected from the group of silicon oxide, silicon oxynitride, and aluminum oxide. The doping process may be a plasma doping process. The method may include forming inner spacers on the sidewalls of the sacrificial material after performing the doping process. The method may include performing an implantation process to introduce dopants into the epitaxial source/drain regions after growing the epitaxial source/drain regions.

In an embodiment, a method may include forming fins of a multi-layer stack over a substrate. The multi-layer stack includes alternating layers of first semiconductor layers and second semiconductor layers. The method may also include forming a first gate structure over the fins. Furthermore, the method may include etching first recesses into the fins. In addition, the method may include removing the first semiconductor layers from the fins. Moreover, the method may include forming a dielectric material between the second semiconductor layers and in the first recesses. The method may also include recessing sidewalls of the dielectric material in the first recesses to form second recesses between adjacent second semiconductor layers. Furthermore, the method may include performing a doping process in the first and second recesses on the dielectric material and the second semiconductor layers. In addition, the method may include forming inner spacers on the recessed sidewalls of the dielectric material. Moreover, the method may include forming source/drain regions in the first recesses adjacent to the inner spacers and the second semiconductor layers. The method may also include performing an ion implantation process to introduce dopants into the source/drain regions. Furthermore, the method may include replacing the first gate structure and the dielectric material with a metal gate structure.

The described embodiments may also include one or more of the following features. The doping process may include a plasma doping process or a tilted ion implantation process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a multi-layer stack over a substrate, the multi-layer stack comprising alternating layers of first semiconductor layers and second semiconductor layers;
removing the first semiconductor layers;
forming a disposable material between the second semiconductor layers;
performing a first implantation process on the disposable material and the second semiconductor layers;
forming source/drain regions adjacent the second semiconductor layers and the disposable material; and
replacing the disposable material with a metal gate structure.

2. The method of claim 1, wherein the disposable material is selected from the group consisting of silicon oxide, silicon oxynitride, and aluminum oxide.

3. The method of claim 1, further comprising:
performing a second implantation process to introduce n-type dopants into the source/drain regions after forming the disposable material between the second semiconductor layers.

4. The method of claim 1, wherein performing the first implantation process on the disposable material and the second semiconductor layers comprises a tilt implantation process.

5. The method of claim 1, wherein the first implantation process comprises a plasma.

6. The method of claim 1, wherein the performing the first implantation process on the disposable material and the second semiconductor layers comprising implanting phosphorus, arsenic, or antimony, germanium, xenon, argon, silicon, nitrogen, boron, boron fluoride, indium, and carbon.

7. The method of claim 1, wherein performing the first implantation process on the disposable material and the second semiconductor layers changes etch selectivity between the second semiconductor layers and the disposable material.

8. The method of claim 1, wherein replacing the disposable material with the metal gate structure further comprises:
removing the disposable material using an etching process that is selective to the disposable material over the second semiconductor layers.

9. The method of claim 1, further comprising:
after performing the first implantation process on the disposable material and the second semiconductor layers, forming inner spacers on sidewalls of the disposable material.

10. The method of claim 9, wherein the inner spacers comprise silicon nitride, silicon oxynitride, or a combination thereof.

11. The method of claim 9, wherein the inner spacers have a convex shape facing the disposable material.

12. A method, comprising:
forming a multi-layer stack over a substrate, the multi-layer stack comprising alternating layers of first semiconductor layers and second semiconductor layers;
patterning the multi-layer stack to define a fin;
forming a recess adjacent to the fin;
selectively removing the first semiconductor layers;
forming a sacrificial material between the second semiconductor layers;
performing a doping process on the sacrificial material and the second semiconductor layers to alter etch selectivity;
growing epitaxial source/drain regions in the recess adjacent to the second semiconductor layers; and
replacing the sacrificial material with a metal gate structure.

13. The method of claim 12, wherein the doping process comprises introducing dopants comprising phosphorus, arsenic, or antimony, germanium, xenon, argon, silicon, nitrogen, boron, boron fluoride, indium, and carbon.

14. The method of claim 12, wherein the sacrificial material comprises a material selected from the group consisting of silicon oxide, silicon oxynitride, and aluminum oxide.

15. The method of claim 12, wherein the doping process is a plasma doping process.

16. The method of claim 12, further comprising:
forming inner spacers on sidewalls of the sacrificial material after performing the doping process.

17. The method of claim 12, further comprising:
performing an implantation process to introduce dopants into the epitaxial source/drain regions after growing the epitaxial source/drain regions.

18. A method, comprising:
forming fins of a multi-layer stack over a substrate, the multi-layer stack including alternating layers of first semiconductor layers and second semiconductor layers;
forming a first gate structure over the fins;
etching first recesses into the fins;
removing the first semiconductor layers from the fins;
forming an dielectric material between the second semiconductor layers and in the first recesses;
recessing sidewalls of the dielectric material in the first recesses to form second recesses between adjacent second semiconductor layers;
performing a doping process in the first and second recesses on the dielectric material and the second semiconductor layers;
forming inner spacers on the recessed sidewalls of the dielectric material;
forming source/drain regions in the first recesses adjacent to the inner spacers and the second semiconductor layers;
performing an ion implantation process to introduce dopants into the source/drain regions; and
replacing the first gate structure and the dielectric material with a metal gate structure.

19. The method of claim 18, wherein the doping process comprises a plasma doping process.

20. The method of claim 18, wherein the doping process comprises a tilted ion implantation process.
